(19) United States
(12) Patent Application Publication
(10) Pub. No.: US 2013/0087959 A1
(43) Pub. Date: Apr. 11, 2013

(54) OPITCALLY TUNED METALIZED LIGHT TO HEAT CONVERSION LAYER FOR WAFER SUPPORT SYSTEM

(71) Applicants: Hung T. Tran, Woodbury, MN (US); Kazuta Saito, Tokyo (JP)

(72) Inventors: Hung T. Tran, Woodbury, MN (US); Kazuta Saito, Tokyo (JP)

(73) Assignee: 3M INNOVATIVE PROPERTIES COMPANY, ST. PAUL, MN (US)

(21) Appl. No.: 13/704,146

(22) PCT Filed: May 27, 2011
(86) PCT No.: PCT/US11/38281

§ 371 Date: Dec. 13, 2012

Related U.S. Application Data
(60) Provisional application No. 61/355,324, filed on Jun. 16, 2010.

(51) Int. Cl. H01L 21/683

(52) U.S. Cl. CPC H01L 21/6835
USPC 269/7; 156/60

(57) ABSTRACT

The present invention is a laminated body including a substrate, a joining layer positioned adjacent the substrate, a photothermal conversion layer positioned adjacent the joining layer, and a light transmitting support positioned adjacent the photothermal conversion layer. The photothermal conversion layer includes a metal absorbing layer.

### CROSS REFERENCE TO RELATED APPLICATION

This application claims the benefit of U.S. Provisional Patent Application No. 61/355,324, filed Jun. 16, 2010, the disclosure of which is incorporated by reference herein in its entirety.

### FIELD

The present invention is related generally to the field of wafer support systems. In particular, the present invention is related to a light to heat conversion layer for use in a wafer support system.

### BACKGROUND

In the semiconductor industry, the demand for higher packaging density and lower cost has increased in recent years. In order to achieve this goal, the substrate, such as a wafer, must be thinned a substantial degree while minimizing the potential that the substrate will break. A challenge to thinning substrates is that it can be difficult to preserve the substrate integrity when it is ground using traditional grinding methods, due in part to the handling of the thin substrates during the fabrication process. Therefore, there is a need for temporarily supporting the substrate during grinding and during fabrication processing. There are currently several concepts used in the field of temporary bonding and support. Most if not all use adhesives, waxes, etc. as an interlayer.

One method currently used for temporarily supporting a substrate is the Wafer Support System (WSS) for ultra thin substrate back-grinding developed by 3M Company located in St. Paul, Minn. This technique utilizes a light transmitting support, such as a glass carrier, having a photothermal conversion layer temporarily coated on the light transmitting support. The light transmitting support is positioned on the substrate such that the photothermal conversion layer is positioned between the light transmitting support and the substrate. In some embodiments, a joining layer is disposed on the substrate such that the photothermal conversion layer is actually in contact with the joining layer. The photothermal conversion layer and the joining layer thus temporarily bond the substrate to the light transmitting support during grinding operations and subsequent processing steps. After the grinding operations and substrate processing steps are completed, the substrate and joining layer are de-bonded from the light transmitting support by applying radiation energy to the photothermal conversion layer. The application of the radiation energy causes the photothermal conversion layer to decompose, allowing separation of the light transmitting support from the joining layer and the substrate.

Current photothermal conversion layers include organic binders, such as for example, carbon in an acrylate binder. One potential limitation of using organic binders in photothermal conversion layers is the inherent thermal limitation of organic binders.

### SUMMARY

In one embodiment, the present invention is a laminated body including a substrate, a joining layer positioned adjacent the substrate, a photothermal conversion layer positioned adjacent the joining layer, and a light transmitting support positioned adjacent the photothermal conversion layer. The photothermal conversion layer includes a metal absorbing layer.

In another embodiment, the present invention is a photothermal conversion layer positionable between a substrate and a light transmitting support. The photothermal conversion layer includes a metal absorbing layer and a spacer layer. The photothermal conversion layer is capable of withstanding temperatures of at least about 180° C. without decomposing.

In another embodiment, the present invention is a method of forming a laminated body. The method includes coating a photothermal conversion layer including a metal absorbing layer onto a light transmitting support, providing a substrate, and adhering the substrate to the photothermal conversion layer using a joining layer to form a laminated body.

In yet another embodiment, a laminated body includes a substrate, a joining layer positioned adjacent the substrate, a photothermal conversion layer positioned adjacent the joining layer, and a light transmitting support positioned adjacent the photothermal conversion layer. The photothermal layer transmits at least about 3% of a wavelength of light required to cure the joining layer and absorbs at least about 10% of a wavelength of electromagnetic radiation required to decompose the photothermal conversion layer.

### BRIEF DESCRIPTION OF THE DRAWINGS

FIG. 1a is a cross-sectional view of a first embodiment of a laminated body of the present invention.

FIG. 1b is a cross-sectional view of a second embodiment of a laminated body of the present invention.

FIG. 1c is a cross-sectional view of a third embodiment of a laminated body of the present invention.

FIG. 1d is a cross-sectional view of a fourth embodiment of a laminated body of the present invention.

FIG. 2 is a cross-sectional view of a photothermal conversion layer of the present invention positioned between a light transmitting support and a substrate.

FIG. 3 is a graph showing percent reflectance, percent transmittance and percent absorptance as a function of wavelength of a modeled embodiment of the present invention.

FIG. 4 is a graph showing percent reflectance, percent transmittance and percent absorptance as a function of wavelength of a modeled embodiment of the present invention.

FIG. 5 is a graph showing percent reflectance, percent transmittance and percent absorptance as a function of wavelength of modeled embodiment of the present invention.

FIG. 6 is a graph showing percent reflectance, percent transmittance and percent absorptance as a function of wavelength of modeled embodiment of the present invention.

FIG. 7 is a graph showing percent reflectance, percent transmittance and percent absorptance as a function of wavelength of modeled embodiment of the present invention.

### DETAILED DESCRIPTION

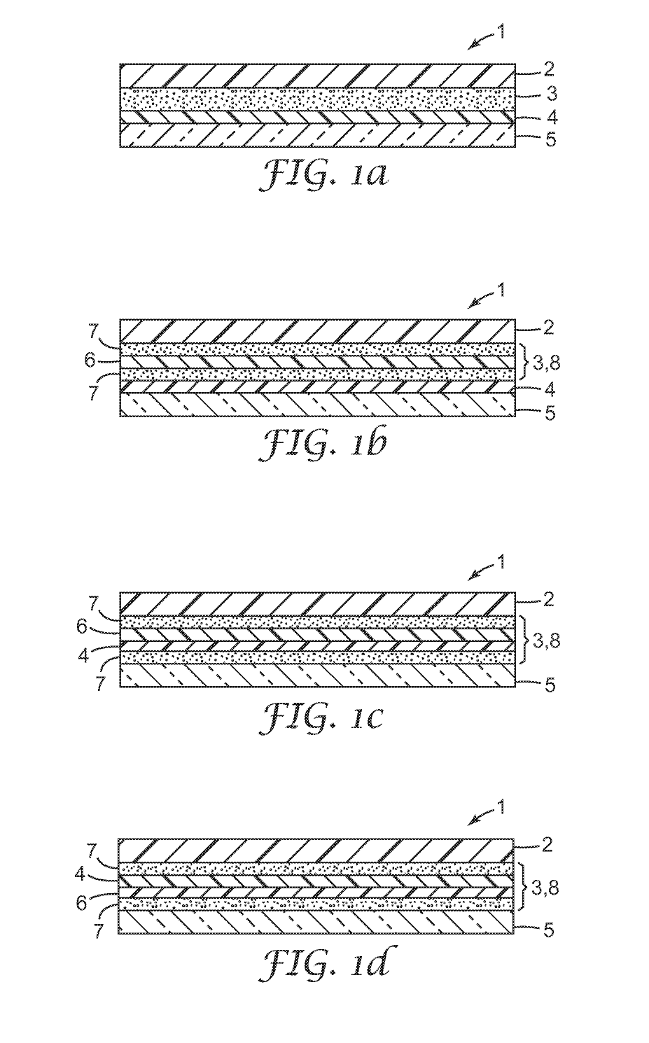

FIGS. 1a, 1b, 1c and 1d show various embodiments of the laminated body of the present invention. In the laminated body 1 of FIG. 1a, a substrate 2 to be ground, a joining layer 3, a photothermal conversion layer 4 and a light transmitting support 5 are laminated in this order. As shown in FIG. 1b, the joining layer 3 may be a double-faced adhesive tape 8 including a first intermediate layer (film) 6 having provided on both surfaces thereof a pressure-sensitive adhesive agent 7. Furthermore, as shown in FIGS. 1c and 1d, the joining layer 3 may be a semi-transparent double-faced adhesive tape 8 integrated with the photothermal conversion layer 4.

One important constituent feature of the laminated body of the present invention is that a photothermal conversion layer is provided somewhere between a substrate to be ground and a light transmitting support. The photothermal conversion layer decomposes upon irradiation with radiation energy such as a laser beam, whereby the substrate can be separated from the support without causing any breakage. The laminated body of the present invention includes a photothermal conversion layer formed of a thin, metal absorbing layer that is optically tuned to absorb laser energy at a specific wavelength. The photothermal conversion layer of the present invention is capable of withstanding fabrication process temperatures equal to the temperatures at which thermal decomposition of the components of the photothermal conversion layer occurs. In one embodiment, the photothermal conversion layer is capable of withstanding temperatures of greater than about 180° C. and particularly greater than about 300° C. In addition, the photothermal conversion layer has high chemical resistance and is semi-transparent, allowing for easy location of fiducial marks on the substrate.

The elements forming the laminated body of the present invention are described in greater detail below.

### Substrate

The substrate may be, for example, a brittle material difficult to thin by conventional methods. Examples thereof include substrates such as silicon, gallium arsenide, sapphire, glass, quartz, gallium nitride and silicon carbide.

### Light Transmitting Support

The light transmitting support is formed of a material capable of transmitting radiation energy, such as a laser beam, and capable of keeping the substrate being ground in a flat state without causing the substrate to break during grinding and conveyance. The light transmittance of the support is not limited as long as it does not prevent the transmittance of a practical intensity level of radiation energy into the photothermal conversion layer to enable the decomposition of the photothermal conversion layer. Examples of useful light transmitting supports include glass plates and acrylic plates. Exemplary glass includes, but is not limited to: quartz, sapphire, and borosilicate.

The light transmitting support is sometimes exposed to heat generated in the photothermal conversion layer when the photothermal conversion layer is irradiated or when a high temperature is produced due to frictional heating during grinding. Particularly, in the case of a silicon wafer, the light transmitting support is sometimes subjected to a high-temperature process to form an oxide film. Accordingly, a light transmitting support having heat resistance, chemical resistance and a low expansion coefficient is selected. Examples of light transmitting support materials having these properties include borosilicate glass available as Pyrex® and Tempax® and alkaline earth boro-aluminosilicate glass such as Corning® #1737 and #7059.

### Photothermal Conversion Layer

The photothermal conversion layer includes a metal absorbing layer. The metal absorbing layer may include a single metal, a mixture of metals including two or more different metals or a metal/metal oxide alloy. The metal absorbing layer is capable of withstanding temperatures of greater than about 180° C. and particularly greater than about 300° C. Depending on the metal selection, the photothermal conversion layer also has high chemical resistance and is semi-transparent. With regard to chemical resistance, the metal is selected such that it will not be affected by the chemicals used during the fabrication process. For example, some fabrication processes use potassium hydroxide, which will remove aluminum. Thus, if the fabrication process is designed to use potassium hydroxide, a metal that is not affected by potassium hydroxide is selected, such as nickel.

The metal absorbing layer may be in the form of a film including a vapor deposited metal film. Although the metal used may vary, generally, any metal that absorbs light at the appropriate wavelength and coverts it to heat can be used. Examples of metals which can be used include, but are not limited to: iron, aluminum, copper, nickel, gold, silver, tin, cobalt, manganese, chromium, germanium, palladium, platinum, rhodium, silicon, tungsten, zinc, titanium and tellurium. Particularly suitable metals include, but are not limited to: aluminum, gold, tin, nickel copper, zinc and chromium. Examples of metal oxide compounds that can be used to form a metal/metal oxide alloy include but are not limited to titanium oxide and aluminum oxide. An example of a suitable metal/metal oxide alloy is aluminum/aluminum oxide alloy, e.g. black alumina with an Al/Al₂O₃ weight ratio of about 25/75. If metal/metal oxide alloys are used as the photothermal conversion layer, the metal content of the alloy is greater than 5%, greater than 10% or even greater than 20% by weight. In one embodiment, the metal absorbing layer typically has a thickness of, for example, between about 1 nm and about 500 nm and particularly between about 10 (nanometers) nm and about 150 nm. In some embodiments, the metal absorbing layer includes more than one layer of metal. In some embodiments, the photothermal conversion layer may be in the form of a multi-layer film stack and include more than one layer. In one embodiment, the photothermal conversion layer may include a transparent spacer layer, such as an inorganic or organic dielectric. When the stack includes a spacer layer, the spacer layer is positioned between the metal absorbing layer and the substrate. The spacer layer functions to tune the optical properties of the photothermal conversion layer, such as absorptance, reflectance and transmittance. For example, a three layer photothermal conversion layer stack with a 149 nm spacer layer can result in about 99% optical absorptance at a wavelength of 1064 nm. Examples of suitable materials for the spacer layer include, but are not limited to: Al₂O₃, Bi₂O₃, CaF₂, HfO₂, ITO, MgF₂, Na₃AlF₆, Sb₂O₃, SiN, SiO, SiO₂, Ta₂O₅, TiO₂, Y₂O₃, ZnS and ZrO₂ as well as other various transparent polymer materials. In one embodiment, the spacer layer is between about 1 nm and about 1,000 nm thick and particularly between about 10 nm and about 300 nm thick.

The photothermal conversion layer may also include a metal reflecting layer. When the stack includes a metal reflecting layer, the metal reflecting layer is positioned between the metal absorbing layer or the spacer layer and the substrate. Examples of metals which can be used include, but are not limited to: iron, aluminum, copper, nickel, gold, silver, tin, cobalt, manganese, chromium, germanium, palladium, platinum, rhodium, silicon, tungsten, zinc, titanium and tellurium. Particularly suitable metals include, but are not limited to: aluminum, gold, tin, nickel copper, zinc and chromium. Similar to the metal absorbing layer, metal/metal oxide alloys may be used as the metal reflecting layer. Examples of metal oxide compounds that can be used to form a metal/metal oxide alloy include but are not limited to titanium oxide and aluminum oxide. In one embodiment, the metal reflecting layer typically has a thickness of between about 1 nm and about 500 nm and particularly between about 3 nm and about 50 nm.

In one embodiment, a multilayer photothermal conversion layer includes at least a metal absorbing layer, a spacer layer and a metal reflecting layer. This design allows for optical tuning of the photothermal conversion layer enabling specific wavelengths of light to be reflected, transmitted and absorbed at varying levels depending on the design. Design parameters that can affect the optical tuning include the refractive index, extinction coefficient and the thickness of each layer.

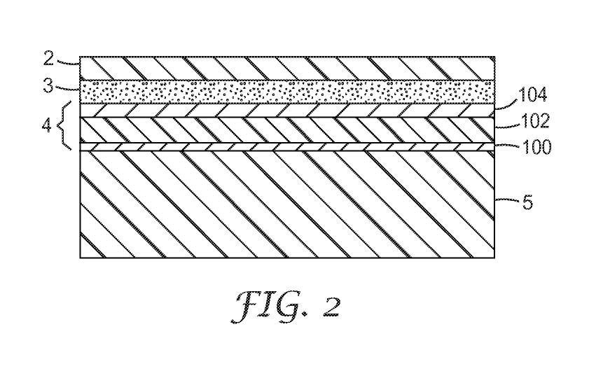

FIG. 2 shows a cross-sectional view of a photothermal conversion layer 4 of the present invention including a metal absorbing layer 100, a spacer layer 102 and a metal reflecting layer 104. The photothermal conversion layer 4 is positioned between a light transmitting support 5 and a substrate 2. A joining layer 3 is also positioned between the substrate 2 and the photothermal conversion layer 4. In one embodiment, the photothermal conversion layer is a metal-dielectric-metal multi-layer film stack including chromium as the metal absorbing layer, silicon dioxide as the spacer layer and aluminum as the metal reflecting layer. In another embodiment, the photothermal conversion layer includes chromium as the metal absorbing layer, silicon dioxide as the spacer layer and nickel as the metal reflecting layer. In yet another embodiment, the photothermal conversion layer includes titanium as the metal absorbing layer, silicon dioxide as the spacer layer and aluminum as the metal reflecting layer. Exemplary thicknesses of a metal-dielectric-metal stack include an about 5 nm metal absorbing layer, an about 149 nm spacer layer and an about 15 nm metal reflecting layer.

Although a three layer metal-dielectric-metal photothermal conversion layer is depicted and described in FIG. 2, additional dielectric-metal layers could be added to the stack to provide additional optical tuning capabilities to the photothermal conversion layer without departing from the scope of the present invention.

A key attribute of the multilayer metal-dielectric-metal photothermal conversion layer design is that the optical properties can be tuned to allow greater transmission of light in the region of the spectrum associated with curing of the joining layer and to increase the absorptance at wavelengths associated with the wavelength of the laser light being used to decompose the photothermal conversion layer. This is particularly important when the joining layer is selected to be UV cureable, i.e., the photothermal conversion layer needs to allow transmission of enough UV radiation to allow for the joining layer to be cured, yet also be able to allow enough absorption of radiation at the wavelength of the laser, e.g. 1,064 nm, to decompose the photothermal conversion layer.

The thickness of the metal in the photothermal conversion layer will vary depending on the metal and its associated refractive index and extinction coefficient. The thickness can be varied to affect the light transmittance, reflectance and absorptance of the photothermal conversion layer. In one embodiment, the light transmission of the photothermal conversion layer at the wavelength associated with curing the joining layer is greater than about 3%, greater than about 5%, greater than about 10% and greater than about 20%. In one embodiment, the electromagnetic radiation, absorptance of the photothermal conversion layer at the wavelength associated with decomposition of the photothermal conversion layer is greater than about 10%, greater than about 15%, greater than about 20% and great than about 50%. In the case where the adhesive used as the joining layer is a UV-curable adhesive, if the thickness of the metal layer(s) is excessively high, the transmittance of the ultraviolet ray for curing the adhesive decreases.

The metals and dielectrics forming the photothermal conversion layer may be deposited by conventional techniques including physical vapor deposition, chemical vapor deposition, plating and the like. In one embodiment, the metal and dielectric layers are deposited using electron-beam physical vapor deposition. Additionally, other techniques may be used to deposit the dielectric layer, particularly if it is polymeric. Polymer films may be used as the dielectric layer and adhered by conventional techniques, e.g. thermal forming, PSA, hot melt adhesive. Liquid monomer(s)/oligomer(s) and optional solvent(s) may be coated on the metal absorbing layer via conventional techniques, e.g. spin coating, notch bar coating and the like, and then dried, if required, and cured to form polymeric spacer layer. The monomer(s) may also be vapor coated followed by curing.

After the substrate has been ground and processed, radiation energy is applied to the photothermal conversion layer in the form of a laser beam or the like and is absorbed and converted into heat energy. The photothermal conversion layer absorbs radiation energy at the wavelength used. The radiation energy is usually a laser beam having a wavelength of about 300 nm to about 11,000 nm and particularly about 300 to nm about 2,000 nm. Specific examples thereof include a YAG laser which emits light at a wavelength of 1,064 nm, a second harmonic generation YAG laser at a wavelength of 532 nm, and a semiconductor laser at a wavelength of from about 780 nm to about 1,300 nm. The heat energy generated abruptly elevates the temperature of the photothermal conversion layer until the temperature reaches the thermal decomposition temperature of the components in the photothermal conversion layer, resulting in heat decomposition and vaporization of the components. The gas generated by the heat decomposition is believed to form a void layer (such as air space) in the photothermal conversion layer and divide the photothermal conversion layer into two parts, whereby the light transmitting support can be separated from the substrate.

### Joining Layer

The joining layer is used for fixing the substrate to be ground to the light transmitting support through the photothermal conversion layer. After the separation of the substrate and the light transmitting support by the decomposition of the photothermal conversion layer, a substrate having the joining layer thereon is obtained. Therefore, the joining layer must be easily separated from the substrate, such as by peeling or solvent cleaning. Thus, the joining layer has an adhesive strength high enough to fix the substrate to the photothermal conversion layer and the light transmitting support yet low enough to permit separation from the substrate. Examples of adhesives which can be used as the joining layer in the present invention include, but are not limited to: rubber-base adhesives obtained by dissolving rubber, elastomer or the like in a solvent, one-part thermosetting adhesives based on epoxy, urethane or the like, two-part thermosetting adhesives based on epoxy, urethane, acryl or the like, hot-melt adhesives, ultraviolet (UV)- or electron beam-curable adhesives based on acryl, epoxy or the like, and water dispersion-type adhesives. UV-curable adhesives obtained by adding a photo-polymerization initiator and, if desired, additives to (1) an oligomer having a polymerizable vinyl group, such as urethane acrylate, epoxy acrylate or polyester acrylate, and/or (2) an acrylic or methacrylic monomer are suitably used. Examples of additives include a thickening agent, a plasticizer, a dispersant, a filler, a fire retardant and a heat stabilizing agent.

In particular, the substrate to be ground, for example a silicon wafer, generally has asperities such as circuit patterns on one side. For the joining layer to fill in the asperities of the substrate to be ground and rendering the thickness of the joining layer uniform, the adhesive used for the joining layer is preferably in a liquid state during coating and laminating and preferably has a viscosity of less than about 10,000 centipoise (cps) at the temperature (for example, 25° C.) of the coating and laminating operations. This liquid adhesive is coated by a spin coating method among various methods described later. As such an adhesive, a UV-curable adhesive, a visible light-curable adhesive or thermo-cured adhesive are suitable options. In one embodiment, the wavelength of light required to cure the joining layer is from about 200 nm to about 800 nm.

The storage modulus of the adhesive is particularly about 100 MPa or more at 25° C. and about 10 MPa or more at 50° C. under the use conditions after removal of the solvent of the adhesive in the case of a solvent-type adhesive, after curing in the case of a curable adhesive, or after normal temperature solidification in the case of a hot-melt adhesive. With this elastic modulus, the substrate to be ground can be prevented from warping or distorting due to stress imposed during grinding and can be uniformly ground to an ultrathin substrate. The storage modulus or elastic modulus as used herein can, for example, be measured on an adhesive sample size of 22.7 mm×10 mm×50 microns in a tensile mode at a frequency of 1 Hz, a strain of 0.04% and a temperature ramp rate of 5° C./min. This storage modulus can be measured using SOLIDS ANALYZER RSA II (trade name) manufactured by Rheometrics, Inc.

A double-faced adhesive tape shown in FIGS. 1(b) to (d) can also be used as the joining layer. In such a double-faced adhesive tape, a pressure-sensitive adhesive layer is usually provided on both surfaces of a backing material. Examples of useful pressure-sensitive adhesives include those mainly comprising acryl, urethane, natural rubber or the like, and those additionally containing a crosslinking agent. Among these, preferred is an adhesive comprising 2-ethylhexylacrylate or butyl acrylate as the main component. For the backing material, paper or a film of plastic or the like is used. Here, the backing must have sufficiently high flexibility so as to permit the separation of the joining layer from the substrate by peeling.

The thickness of the joining layer is not particularly limited as long as it can ensure the thickness uniformity required for the grinding of the substrate to be ground and can sufficiently absorb the asperities on the substrate surface. The thickness of the joining layer is typically from about 10 to about 150 microns, particularly from about 25 to about 100 microns.

### Other Useful Additives

Because the substrate to be ground can be a wafer having formed thereon a circuit, the wafer circuit may be damaged by radiation energy such as a laser beam reaching the wafer through the light transmitting support, the photothermal conversion layer and the joining layer. To avoid such circuit damage, a light absorbing dye capable of absorbing light at the wavelength of the radiation energy or a light reflecting pigment capable of reflecting the light may be contained in any of the layers constituting the laminated body or may be contained in a layer separately provided between the photothermal conversion layer and the substrate. Examples of light absorbing dyes include dyes having an absorption peak in the vicinity of the wavelength of the laser beam used (for example, phthalocyanine-based dyes and cyanine-based dyes). Examples of light reflecting pigments include inorganic white pigments such as titanium oxide.

### EXAMPLES

The present invention is more particularly described in the following examples that are intended as illustrations only, since numerous modifications and variations within the scope of the present invention will be apparent to those skilled in the art. Unless otherwise noted, all parts, percentages, and ratios reported in the following examples are on a weight basis.

### Example 1

A metal-dielectric-metal, multi-layer film stack was coated onto a glass carrier as a photothermal conversion layer. A 151 mm diameter×0.7 mm thick glass carrier was coated sequentially with chromium, silicon dioxide and aluminum using conventional electron beam physical vapor deposition techniques. The target layer thicknesses were 5 nm for chromium, 149 nm for silicon dioxide and 15 nm for aluminum. Prior to coating the layers, the glass was cleaned with soap and water and treated with an oxygen plasma using conventional techniques.

The glass carrier with the photothermal conversion layer was laminated to a 150 mm diameter silicon wafer using an adhesive joining layer, producing Example 1. The adhesive was in contact with the metal coating of the carrier. 3M® Liquid UV-Curable Adhesive LC-3200 (available from the 3M Company, St. Paul, Minn.) was used as the adhesive joining layer to laminate the carrier and silicon wafer using a 3M wafer support system bonder, model number WSS8101M (available from Tazmo Co., Ltd., Freemont, Calif.). Pressure was applied by the apparatus flatting disc for 7 seconds during the vacuum bonding step. The adhesive was UV cured for 25 seconds using a Fusion Systems D bulb, 300 watt/inch.

After lamination, the glass carrier-silicon wafer laminate was heat aged in an oven at 250° C. for 1 hour. Following heat aging, the glass carrier-silicon wafer laminate was laser rastered using a PowerLine E Series laser (available from Rofin-Sinar Technologies, Inc., Stuttgart, Germany) operating at 1,064 nm wavelength. Rastering was conducted at a power of 38 watt, a raster speed of 2000 mm/s and with a raster pitch of 200 microns. The chromium, silicon dioxide, aluminum photothermal conversion layer decomposed and the glass carrier was successfully removed from the silicon wafer.

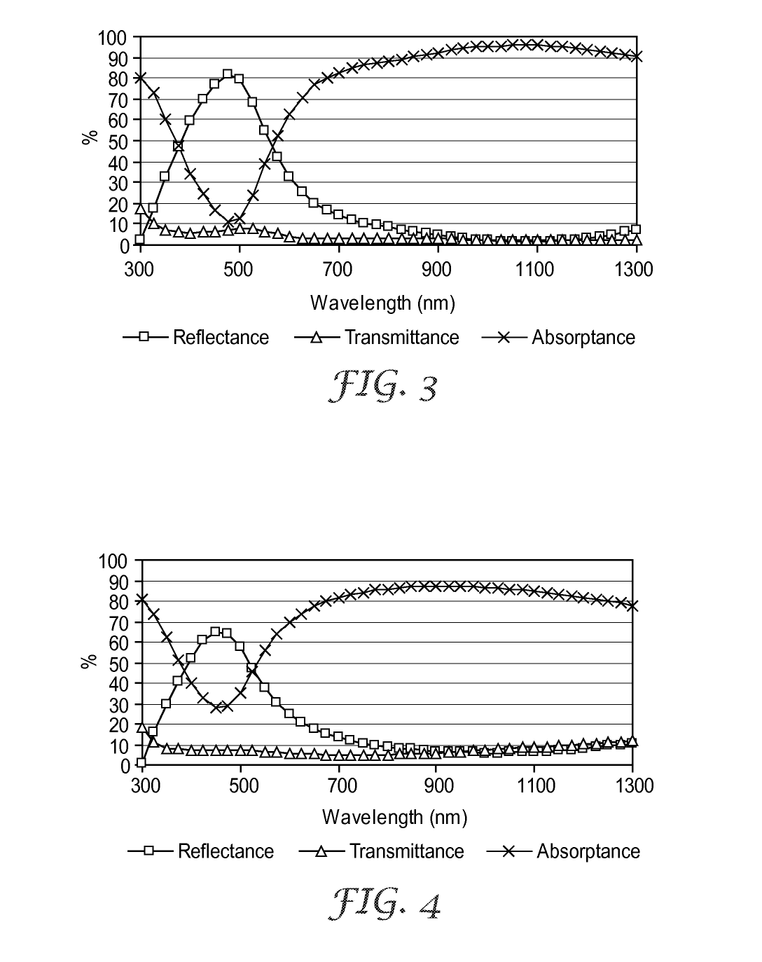

A mathematical optical model was used to calculate the optical characteristics of the photothermal conversion layer as a function of the wavelength of light. The calculated percent reflectance, percent transmittance and percent absorptance as a function of wavelength, λ, are shown in Table 1 and plotted in FIG. 3.

TABLE 1

| λ | Reflectance | Transmittance | Absorptance |
|---|---|---|---|
| (nm) | (%) | (%) | (%) |
| 300 | 2.04 | 17.48 | 80.49 |
| 325 | 17.42 | 9.95 | 72.63 |
| 350 | 32.64 | 7.02 | 60.35 |
| 375 | 46.51 | 6.14 | 47.35 |
| 400 | 59.75 | 5.90 | 34.35 |
| 425 | 69.73 | 5.99 | 24.28 |
| 450 | 77.12 | 6.52 | 16.36 |
| 475 | 81.66 | 7.28 | 11.06 |
| 500 | 79.33 | 7.84 | 12.84 |
| 525 | 68.53 | 7.58 | 23.89 |
| 550 | 54.66 | 6.58 | 38.76 |
| 575 | 42.36 | 5.37 | 52.27 |
| 600 | 32.66 | 4.34 | 63.00 |
| 625 | 25.41 | 3.56 | 71.03 |
| 650 | 20.06 | 2.99 | 76.95 |
| 675 | 16.73 | 3.02 | 80.25 |
| 700 | 14.27 | 3.07 | 82.66 |
| 725 | 12.16 | 2.99 | 84.85 |
| 750 | 10.50 | 2.93 | 86.56 |
| 775 | 9.31 | 3.05 | 87.64 |
| 800 | 8.35 | 3.17 | 88.48 |
| 825 | 7.52 | 3.23 | 89.25 |
| 850 | 6.55 | 3.33 | 90.12 |
| 875 | 5.54 | 3.20 | 91.26 |
| 900 | 4.64 | 3.09 | 92.27 |
| 925 | 3.77 | 2.87 | 93.36 |
| 950 | 3.00 | 2.68 | 94.32 |
| 975 | 2.44 | 2.68 | 94.88 |
| 1000 | 2.01 | 2.68 | 95.31 |
| 1025 | 1.76 | 2.67 | 95.57 |
| 1050 | 1.61 | 2.67 | 95.72 |
| 1075 | 1.58 | 2.68 | 95.74 |
| 1100 | 1.67 | 2.68 | 95.64 |
| 1125 | 1.92 | 2.68 | 95.40 |
| 1150 | 2.28 | 2.68 | 95.03 |
| 1175 | 2.76 | 2.69 | 94.55 |
| 1200 | 3.39 | 2.69 | 93.92 |
| 1225 | 4.23 | 2.68 | 93.09 |
| 1250 | 5.13 | 2.67 | 92.20 |
| 1275 | 6.06 | 2.65 | 91.29 |
| 1300 | 7.05 | 2.63 | 90.31 |
| — | — | — | — |

Surprisingly, the adhesive joining layer did not decompose and no adverse effects on the wafer substrate were noted during laser rastering of the photothermal conversion layer, which occurred at very high temperatures in which the metal was basically vaporized.

To test the chemical resistance of the photothermal conversion layer, two additional coated glass carriers were prepared, as described above, with the previously indicated chromium/silicon dioxide/aluminum coating. Testing was conducted prior to applying the adhesive joining layer and laminating the carrier to a wafer. Each carrier was subjected to a specific soak test. The first test involved soaking a coated glass carrier in Microposit Remover 1165, a solution comprising tetramethylammonium hydroxide (available from Rohm and Haas Electronic Materials, LLC, Marlborough, Mass.) for 5 minutes at 25° C. The second test involved soaking a coated glass carrier in a 5% (by weight) potassium hydroxide/dimethyl sulfoxide solution for 90 minutes at 60° C. In both cases, the coated glass carrier passed the soak test, with the chromium/silicon dioxide/aluminum coating remaining adhered to the glass surface.

### Example 2

A metal-dielectric-metal, multi-layer film stack was coated onto a glass carrier as a photothermal conversion layer, as described in Example 1, except that the aluminum target thickness was 4 nm. The coated glass carrier was laminated to a silicon wafer following the procedure described in Example 1, producing Example 2. The glass carrier-silicon wafer laminate was heat aged and then laser rastered, as described in Example 1. The chromium, silicon dioxide, aluminum photothermal conversion layer decomposed and the glass carrier was successfully removed from the silicon wafer.

Surprisingly, the adhesive joining layer did not decompose and no adverse effects on the wafer substrate were noted during laser rastering of the photothermal conversion layer, which occurred at very high temperatures in which the metal was basically vaporized.

### Example 3

A metal-dielectric-metal, multi-layer film stack was coated onto a glass carrier as a photothermal conversion layer, as described in Example 1, except that the aluminum target thickness was 10 nm. The coated glass carrier was laminated to a silicon wafer following the procedure described in Example 1, producing Example 3. The glass carrier-silicon wafer laminate was heat aged and then laser rastered, as described in Example 1. The chromium, silicon dioxide, aluminum photothermal conversion layer decomposed and the glass carrier was successfully removed from the silicon wafer.

Surprisingly, the adhesive joining layer did not decompose and no adverse effects on the wafer substrate were noted during laser rastering of the photothermal conversion layer, which occurred at very high temperatures in which the metal was basically vaporized.

### Example 4

A metal-dielectric-metal, multi-layer film stack was coated onto a glass carrier as a photothermal conversion layer, as described in Example 1, except that the aluminum target thickness was 30 nm. The coated glass carrier was laminated to a silicon wafer following the procedure described in Example 1, producing Example 4. The glass carrier-silicon wafer laminate was heat aged and then laser rastered, as described in Example 1. The chromium, silicon dioxide, aluminum photothermal conversion layer decomposed and the glass carrier was successfully removed from the silicon wafer.

Surprisingly, the adhesive joining layer did not decompose and no adverse effects on the wafer substrate were noted during laser rastering of the photothermal conversion layer, which occurred at very high temperatures in which the metal was basically vaporized.

### Example 5

A metal-dielectric-metal, multi-layer film stack was coated onto a glass carrier as a photothermal conversion layer, as described in Example 1, except that the multi-layer film stack included chromium, silicon dioxide and chromium with target layer thicknesses of 5 nm, 149 nm and 15 nm, respectively. The coated glass carrier was laminated to a silicon wafer following the procedure described in Example 1, producing Example 5. The glass carrier-silicon wafer laminate was heat aged and then laser rastered, as described in Example 1. The chromium, silicon dioxide, chromium photothermal conversion layer decomposed and the glass carrier was successfully removed from the silicon wafer. The mathematical model described above in Example 1 was used to calculate the optical characteristics of the photothermal conversion layer as a function of the wavelength of light. The calculated percent reflectance, percent transmittance and percent absorptance as a function of wavelength, λ, are shown in Table 2 and plotted in FIG. 4.

TABLE 2

| λ | Reflectance | Transmittance | Absorptance |
|---|---|---|---|
| (nm) | (%) | (%) | (%) |
| 300 | 0.84 | 18.53 | 80.63 |
| 325 | 15.64 | 11.13 | 73.23 |
| 350 | 29.72 | 8.22 | 62.06 |
| 375 | 41.11 | 7.80 | 51.10 |
| 400 | 52.19 | 7.42 | 40.39 |
| 425 | 60.40 | 7.08 | 32.52 |
| 450 | 64.84 | 7.08 | 28.08 |
| 475 | 64.33 | 7.26 | 28.41 |
| 500 | 57.24 | 7.39 | 35.37 |
| 525 | 46.99 | 7.03 | 45.98 |
| 550 | 37.54 | 6.54 | 55.92 |
| 575 | 30.24 | 6.06 | 63.69 |
| 600 | 24.75 | 5.71 | 69.55 |
| 625 | 20.57 | 5.45 | 73.99 |
| 650 | 17.40 | 5.25 | 77.35 |
| 675 | 15.03 | 5.10 | 79.87 |
| 700 | 13.23 | 4.99 | 81.77 |
| 725 | 11.76 | 5.00 | 83.25 |
| 750 | 10.59 | 5.03 | 84.38 |
| 775 | 9.67 | 5.09 | 85.24 |
| 800 | 8.93 | 5.17 | 85.90 |
| 825 | 8.34 | 5.27 | 86.39 |
| 850 | 7.69 | 5.50 | 86.81 |
| 875 | 7.18 | 5.73 | 87.09 |
| 900 | 6.77 | 5.99 | 87.25 |
| 925 | 6.45 | 6.26 | 87.29 |
| 950 | 6.20 | 6.58 | 87.22 |
| 975 | 6.00 | 6.95 | 87.05 |
| 1000 | 5.91 | 7.33 | 86.76 |
| 1025 | 5.95 | 7.67 | 86.38 |
| 1050 | 6.06 | 8.03 | 85.91 |
| 1075 | 6.23 | 8.41 | 85.35 |
| 1100 | 6.47 | 8.82 | 84.71 |
| 1125 | 6.79 | 9.20 | 84.01 |
| 1150 | 7.18 | 9.56 | 83.26 |
| 1175 | 7.58 | 10.00 | 82.42 |
| 1200 | 8.06 | 10.40 | 81.54 |
| 1225 | 8.64 | 10.74 | 80.62 |
| 1250 | 9.23 | 11.06 | 79.71 |
| 1275 | 9.83 | 11.33 | 78.84 |
| 1300 | 10.44 | 11.62 | 77.95 |
| — | — | — | — |

Surprisingly, the adhesive joining layer did not decompose and no adverse effects on the wafer substrate were noted during laser rastering of the photothermal conversion layer, which occurred at very high temperatures in which the metal was basically vaporized.

### Example 6

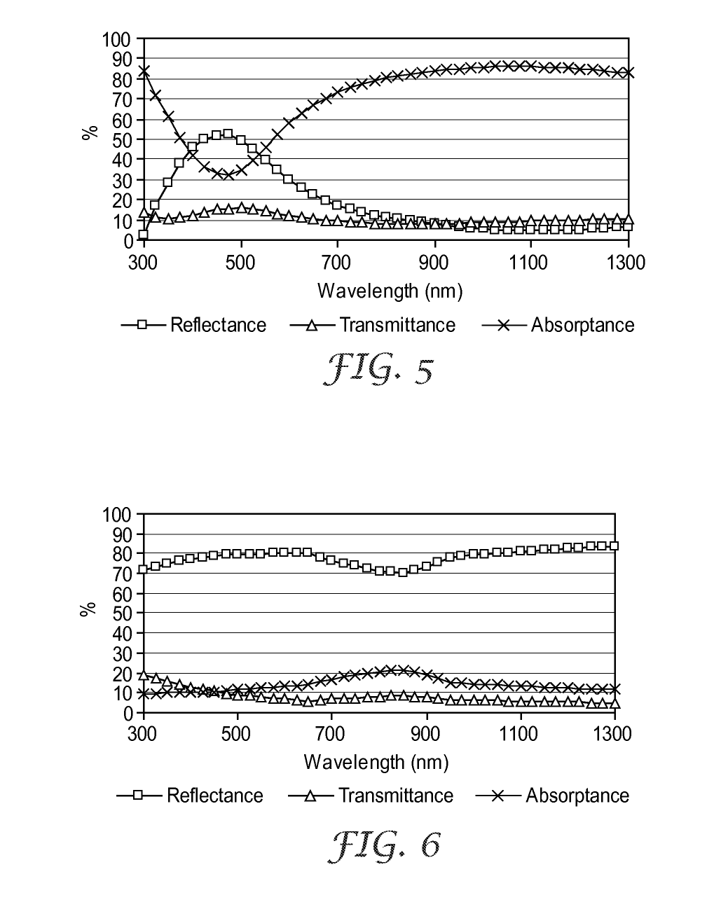

A metal-dielectric-metal, multi-layer film stack was coated onto a glass carrier as a photothermal conversion layer, as described in Example 1, except that the multi-layer film stack included chromium, silicon dioxide and nickel with target layer thicknesses of 5 nm, 149 nm and 15 nm, respectively. The coated glass carrier was laminated to a silicon wafer following the procedure described in Example 1, producing Example 6. The glass carrier-silicon wafer laminate was heat aged and then laser rastered, as described in Example 1. The chromium, silicon dioxide, nickel photothermal conversion layer decomposed and the glass carrier was successfully removed from the silicon wafer. The mathematical model described above in Example 1 was used to calculate the optical characteristics of the photothermal conversion layer as a function of the wavelength of light. The calculated percent reflectance, percent transmittance and percent absorptance as a function of wavelength, λ, are shown in Table 3 and plotted in FIG. 5.

TABLE 3

| λ | Reflectance | Transmittance | Absorptance |
|---|---|---|---|
| (nm) | (%) | (%) | (%) |
| 300 | 2.48 | 13.72 | 83.79 |
| 325 | 16.83 | 11.13 | 72.04 |
| 350 | 28.51 | 10.39 | 61.10 |
| 375 | 37.69 | 11.16 | 51.15 |
| 400 | 45.57 | 12.34 | 42.10 |
| 425 | 50.03 | 13.78 | 36.19 |
| 450 | 51.90 | 15.02 | 33.08 |
| 475 | 52.04 | 15.57 | 32.39 |
| 500 | 49.49 | 15.80 | 34.70 |
| 525 | 45.06 | 15.28 | 39.66 |
| 550 | 39.73 | 14.34 | 45.94 |
| 575 | 34.58 | 13.30 | 52.12 |
| 600 | 29.90 | 12.29 | 57.81 |
| 625 | 25.81 | 11.39 | 62.80 |
| 650 | 22.39 | 10.60 | 67.02 |
| 675 | 19.55 | 9.91 | 70.54 |
| 700 | 17.24 | 9.33 | 73.43 |
| 725 | 15.27 | 8.90 | 75.83 |
| 750 | 13.65 | 8.55 | 77.80 |
| 775 | 12.32 | 8.26 | 79.42 |
| 800 | 11.28 | 8.15 | 80.56 |
| 825 | 10.41 | 8.05 | 81.53 |
| 850 | 9.42 | 8.07 | 82.51 |
| 875 | 8.59 | 8.13 | 83.28 |
| 900 | 7.85 | 8.22 | 83.93 |
| 925 | 7.21 | 8.32 | 84.47 |
| 950 | 6.60 | 8.43 | 84.97 |
| 975 | 6.02 | 8.57 | 85.41 |
| 1000 | 5.54 | 8.72 | 85.74 |
| 1025 | 5.20 | 8.84 | 85.96 |
| 1050 | 4.95 | 9.01 | 86.04 |
| 1075 | 4.78 | 9.19 | 86.03 |
| 1100 | 4.67 | 9.39 | 85.94 |
| 1125 | 4.68 | 9.56 | 85.76 |
| 1150 | 4.76 | 9.71 | 85.53 |
| 1175 | 4.86 | 9.89 | 85.25 |
| 1200 | 5.08 | 10.05 | 84.87 |
| 1225 | 5.45 | 10.19 | 84.36 |
| 1250 | 5.87 | 10.30 | 83.82 |
| 1275 | 6.32 | 10.39 | 83.29 |
| 1300 | 6.80 | 10.48 | 82.72 |
| — | — | — | — |

Surprisingly, the adhesive joining layer did not decompose and no adverse effects on the wafer substrate were noted during laser rastering of the photothermal conversion layer, which occurred at very high temperatures in which the metal was basically vaporized.

### Example 7

A single metal film layer, aluminum, was coated onto an about 2 inch (5.1 cm)×3 inch (7.6 cm) glass slide as a photothermal conversion layer, using conventional electron beam physical vapor deposition techniques. The target metal layer thickness was 15 nm. The coated glass slide was laminated to a silicon wafer by hand by coating a thin layer of 3M® Liquid UV-Curable Adhesive LC-3200 onto the wafer and placing the aluminum coated side of the glass slide on the adhesive. The adhesive was cured as described in Example 1. The glass slide-silicon wafer laminate was laser rastered as described in Example 1. The aluminum photothermal conversion layer decomposed and the glass slide was successfully removed from the silicon wafer. The mathematical model described above in Example 1 was used to calculate the optical characteristics of the photothermal conversion layer as a function of the wavelength of light. The calculated percent reflectance, percent transmittance and percent absorptance as a function of wavelength, λ, are shown in Table 4 and plotted in FIG. 6.

TABLE 4

| λ | Reflectance | Transmittance | Absorptance |
|---|---|---|---|
| (nm) | (%) | (%) | (%) |
| 300 | 71.56 | 18.97 | 9.47 |
| 325 | 73.26 | 17.01 | 9.72 |
| 350 | 74.75 | 15.38 | 9.88 |
| 375 | 76.12 | 13.93 | 9.95 |
| 400 | 77.05 | 12.91 | 10.04 |
| 425 | 77.89 | 11.85 | 10.26 |
| 450 | 78.60 | 10.80 | 10.60 |
| 475 | 79.27 | 9.71 | 11.02 |
| 500 | 79.67 | 8.91 | 11.42 |
| 525 | 79.61 | 8.44 | 11.95 |
| 550 | 79.66 | 7.97 | 12.37 |
| 575 | 79.99 | 7.40 | 12.61 |
| 600 | 80.06 | 6.81 | 13.13 |
| 625 | 80.14 | 6.29 | 13.57 |
| 650 | 80.27 | 5.82 | 13.91 |
| 675 | 78.25 | 6.36 | 15.39 |
| 700 | 76.25 | 6.90 | 16.85 |
| 725 | 75.18 | 7.04 | 17.77 |
| 750 | 74.19 | 7.17 | 18.64 |
| 775 | 72.68 | 7.63 | 19.69 |
| 800 | 71.20 | 8.09 | 20.71 |
| 825 | 70.63 | 8.33 | 21.04 |
| 850 | 70.09 | 8.56 | 21.35 |
| 875 | 71.72 | 8.19 | 20.09 |
| 900 | 73.30 | 7.83 | 18.87 |
| 925 | 75.86 | 7.18 | 16.96 |
| 950 | 78.26 | 6.59 | 15.15 |
| 975 | 78.74 | 6.44 | 14.83 |
| 1000 | 79.20 | 6.29 | 14.51 |
| 1025 | 79.65 | 6.15 | 14.21 |
| 1050 | 80.08 | 6.01 | 13.91 |
| 1075 | 80.51 | 5.87 | 13.62 |
| 1100 | 80.92 | 5.74 | 13.35 |
| 1125 | 81.32 | 5.61 | 13.08 |
| 1150 | 81.70 | 5.48 | 12.82 |
| 1175 | 82.08 | 5.36 | 12.57 |
| 1200 | 82.44 | 5.24 | 12.32 |
| 1225 | 82.79 | 5.12 | 12.09 |
| 1250 | 83.14 | 5.01 | 11.86 |
| 1275 | 83.47 | 4.90 | 11.63 |
| 1300 | 83.79 | 4.79 | 11.42 |
| — | — | — | — |

Surprisingly, the adhesive joining layer did not decompose and no adverse effects on the wafer substrate were noted during laser rastering of the photothermal conversion layer, which occurred at very high temperatures in which the metal was basically vaporized.

### Example 8

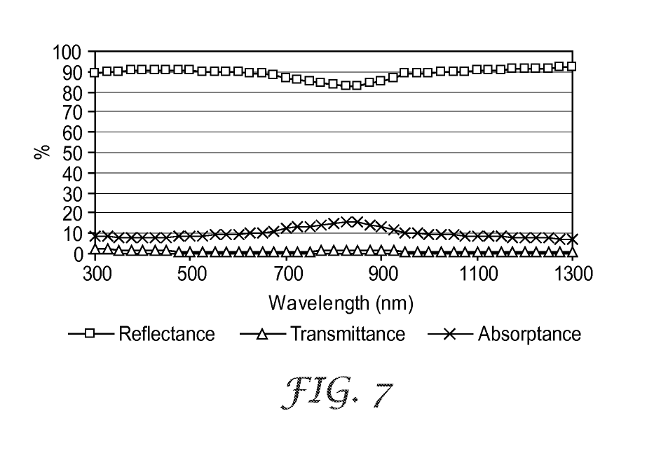

A single metal film layer, aluminum, was coated onto a glass slide as a photothermal conversion layer using conventional electron beam physical vapor deposition techniques. The target metal layer thickness was 30 nm. The coated glass slide was laminated to a silicon wafer following the procedure described in Example 7, producing Example 8. The glass slide-silicon wafer laminate was laser rastered as described in Example 1. The aluminum photothermal conversion layer decomposed and the glass carrier was successfully removed from the silicon wafer. The mathematical model described above in Example 1 was used to calculate the optical characteristics of the photothermal conversion layer as a function of the wavelength of light. The calculated percent reflectance, percent transmittance and percent absorptance as a function of wavelength, λ, are shown in Table 5 and plotted in FIG. 7.

TABLE 5

| λ | Reflectance | Transmittance | Absorptance |
|---|---|---|---|
| (nm) | (%) | (%) | (%) |
| 300 | 89.32 | 2.40 | 8.28 |
| 325 | 89.68 | 2.09 | 8.22 |
| 350 | 90.03 | 1.85 | 8.12 |
| 375 | 90.37 | 1.65 | 7.98 |
| 400 | 90.58 | 1.52 | 7.89 |
| 425 | 90.68 | 1.39 | 7.93 |
| 450 | 90.67 | 1.25 | 8.08 |
| 475 | 90.59 | 1.11 | 8.30 |
| 500 | 90.46 | 1.01 | 8.53 |
| 525 | 90.16 | 0.97 | 8.86 |
| 550 | 89.96 | 0.93 | 9.11 |
| 575 | 89.91 | 0.86 | 9.22 |
| 600 | 89.64 | 0.79 | 9.57 |
| 625 | 89.40 | 0.73 | 9.87 |
| 650 | 89.24 | 0.67 | 10.08 |
| 675 | 88.03 | 0.81 | 11.16 |
| 700 | 86.80 | 0.95 | 12.25 |
| 725 | 86.06 | 1.02 | 12.93 |
| 750 | 85.36 | 1.08 | 13.56 |
| 775 | 84.42 | 1.22 | 14.35 |
| 800 | 83.49 | 1.38 | 15.14 |
| 825 | 83.20 | 1.46 | 15.34 |
| 850 | 82.92 | 1.55 | 15.53 |
| 875 | 84.17 | 1.45 | 14.38 |
| 900 | 85.34 | 1.35 | 13.31 |
| 925 | 87.10 | 1.18 | 11.72 |
| 950 | 88.69 | 1.03 | 10.28 |
| 975 | 89.00 | 1.01 | 9.99 |
| 1000 | 89.30 | 0.99 | 9.72 |
| 1025 | 89.58 | 0.96 | 9.45 |
| 1050 | 89.85 | 0.94 | 9.20 |
| 1075 | 90.11 | 0.92 | 8.96 |
| 1100 | 90.36 | 0.90 | 8.73 |
| 1125 | 90.60 | 0.88 | 8.51 |
| 1150 | 90.84 | 0.86 | 8.30 |
| 1175 | 91.06 | 0.84 | 8.10 |
| 1200 | 91.27 | 0.82 | 7.91 |
| 1225 | 91.47 | 0.80 | 7.72 |
| 1250 | 91.67 | 0.79 | 7.54 |
| 1275 | 91.86 | 0.77 | 7.37 |
| 1300 | 92.04 | 0.75 | 7.21 |
| — | — | — | — |

Surprisingly, the adhesive joining layer did not decompose and no adverse effects on the wafer substrate were noted during laser rastering of the photothermal conversion layer, which occurred at very high temperatures in which the metal was basically vaporized.

### Example 9

A metal/metal oxide alloy, black alumina (Al/Al₂O₃ 25/75 by weight), was coated onto a glass carrier as a photothermal conversion layer using conventional electron beam physical vapor deposition techniques. The target thickness of the layer was about 200 nm. The coated glass carrier was laminated to a silicon wafer following the procedure described in Example 1, producing Example 9. The glass carrier-silicon wafer laminate was heat aged and then laser rastered, as described in Example 1. The Al/Al₂O₃ photothermal conversion layer decomposed and the glass carrier was successfully removed from the silicon wafer.

In addition to the above examples and mathematical modeling data, the percent absorptance of a layer of chromium at varying thicknesses was calculated using the mathematical model. The data is shown Table 6. Absorptance values of greater than 30% were calculated for all chromium thicknesses evaluated

TABLE 6

| Chromium | % Absorp- |
|---|---|
| Layer | tance @ |
| Thickness | 1,064 nm |
| (nm) | wavelength |
| 5 | 31 |
| 10 | 38 |
| 20 | 36 |
| 40 | 31 |
| 100 | 37 |

Although the present invention has been described with reference to preferred embodiments, workers skilled in the art will recognize that changes may be made in form and detail without departing from the spirit and scope of the invention.

1. A laminated body comprising:
a substrate;
a joining layer positioned adjacent the substrate;
a photothermal conversion layer positioned adjacent the joining layer, wherein the photothermal layer comprises a metal absorbing layer; and
a light transmitting support positioned adjacent the photothermal conversion layer.

2. The laminated body of claim 1, wherein the metal absorbing layer is selected from at least one of the group consisting of: iron, aluminum, copper, nickel, gold, silver, tin, cobalt, manganese, chromium, germanium, palladium, platinum, rhodium, silicon, tungsten, zinc, titanium, tellurium, titanium oxide and aluminum oxide.

3. The laminated body of claim 1, wherein the photothermal conversion layer further comprises a spacer layer positioned between the metal absorbing layer and the substrate.

4. The laminated body of claim 3, wherein the spacer layer is selected from the group consisting of: Al₂O₃, Bi₂O₃, CaF₂, HfO₂, ITO, MgF₂, Na₃AlF₆, Sb₂O₃, SiN, SiO, SiO₂, Ta₂O₅, TiO₂, Y₂O₃, ZnS and ZrO₂.

5. The laminated body of claim 1, wherein the photothermal conversion layer further comprises a metal reflecting layer positioned between the metal absorbing layer and the substrate.

6. The laminated body of claim 1, wherein the joining layer is selected from the group consisting of: a photocurable, thermocurable or hot melt adhesive.

7. A photothermal conversion layer positionable between a substrate and a light transmitting support, the photothermal conversion layer comprising:
a metal absorbing layer; and
a spacer layer;
wherein the photothermal conversion layer is capable of withstanding temperatures of at least about 180° C. without decomposing.

8. The photothermal conversion layer of claim 7, further comprising a metal reflecting layer positioned adjacent the spacer layer.

9. A method of forming a laminated body, the method comprising:
i. coating a photothermal conversion layer comprising a metal absorbing layer onto a light transmitting support;
ii. providing a substrate; and
iii. adhering the substrate to the photothermal conversion layer using a joining layer to form a laminated body.

10. The method of claim 9, wherein the photothermal conversion layer further comprises a spacer layer positioned adjacent the metal absorbing layer.

11. The method of claim 9, wherein the photothermal conversion layer further comprises a metal reflecting layer positioned adjacent the joining layer.

12. A laminated body comprising:
a substrate;
a joining layer positioned adjacent the substrate;
a photothermal conversion layer positioned adjacent the joining layer, wherein the photothermal layer transmits at least about 3% of a wavelength of light required to cure the joining layer and absorbs at least about 10% of a wavelength of electromagnetic radiation required to decompose the photothermal conversion layer; and
a light transmitting support positioned adjacent the photothermal conversion layer.

13. The laminated body of claim 12, wherein the wavelength of light required to cure the joining layer is from about 200 nm to about 800 nm.

14. The laminated body of claim 12 wherein the wavelength of electromagnetic radiation required to decompose the photothermal conversion layer is from about 500 nm to about 2,000 nm.
